(19) United States
(12) Patent Application Publication
(10) Pub. No.: US 2003/0117067 A1
(43) Pub. Date: Jun. 26, 2003

(54) OLED having improved light extraction efficiency

(76) Inventors: Daniel B. Roitman, Menlo Park, CA (US); Homer Antoniadis, Mountain View, CA (US); Annette V. Grot, Cupertino, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/026,051

(22) Filed: Dec. 21, 2001

(51) Int. Cl. H05B 33/00

(52) U.S. Cl. 313/504

(57) ABSTRACT

An OLED having top and bottom electrodes with an organic light-emitting layer sandwiched between these electrodes. The bottom electrode layer includes a planar conducting layer having a plurality of protrusions thereon. The light-emitting layer covers the bottom electrode with a first surface in contact with the first electrode layer and its second surface having raised areas over the protrusions. The top electrode layer includes a layer of conductive material in contact with the second surface. One of the top and bottom electrodes is transparent to light generated in the light-emitting layer. The size and spacing of the protrusions is chosen to provide increased light output from the transparent one of the top and bottom electrodes relative to the light output that would be obtained in the absence of the protrusions.

### FIELD OF THE INVENTION

The present invention relates to organic light-emitting diodes (OLEDs), and more particularly, to structures for improving the emission of such devices.

### BACKGROUND OF THE INVENTION

Organic light emitting devices (OLEDs) are emissive displays consisting of a transparent substrate consisting of a transparent conducting material, such as Indium Tin oxide (ITO), one or more organic layers, and a cathode made by evaporating or sputtering a metal of low work function characteristics, such as Ca or Mg or Al alloys. The organic layers are chosen so as to provide charge injection and transport from both electrodes into the electroluminescent organic layer (ETL) where the charges recombine, emitting light. There may be one or more organic hole transport layers (HTL) between the ITO and the EL, as well as one or more electron injection and transporting layers (EL) between the cathode and the EL.

OLEDs hold out the promise of providing inexpensive displays. In principle, these devices can be manufactured on flexible substrates and fabricated using “roll-to-roll” processing equipment. Inexpensive equipment for such fabrication operations such as polymer film coating devices, metal evaporators and lithography equipment capable of providing the deposition of the various layers are already available. For example, Web coating devices for thin polymer films that are a few feet wide can operate at a feed rate of hundreds of feet per minute.

The index of refraction of the transport and EL layers is much higher than that of air. Hence, light that does not strike the air interface at near normal incidence is trapped in the OLED where it is absorbed after several reflections from the boundaries of the OLED. Hence, the efficiency with which light is generated per watt of power can be relatively low, particularly in OLEDs having large “pixels.”

For the purposes of this discussion, a pixel will be defined to be an OLED that is powered separately and addressed separately. Conventional pixelated color displays having red, blue, and green OLED pixels are known to the art. To display an object having a particular color, a number of small pixels are energized to create an image at the desired location. A second type of display that is limited to displaying one of a plurality of objects utilizes pixels that display a single color and have the shape of the object. For example, the bars of an alphanumeric display may be constructed from single OLED pixels. This type of display requires significantly fewer addressing circuits, and hence, has the potential for providing very inexpensive displays in those applications that are amenable to these large “pixel” displays.

If the pixels are relatively small, small light-pipe structures can be provided at the boundary of the pixels to capture the trapped light and allow it to exit in the proper direction. Light piping arrangements based on reflectors between conventional LEDs are known to the art. However, if the pixel area is large compared to the distance over which the trapped light will be absorbed, light piping structures are of little use.

In the case of OLEDs, the materials utilized for the various layers are relatively opaque compared to materials used in conventional LEDs. As a result, edge light pipe structures actually degrade the display performance, since the pixel will appear to have a non-uniform light emission pattern in which the edges are much brighter than the middle. In addition, the cost of fabricating OLEDs with light pipes around each pixel is significant, and hence, detracts from the low-cost advantage enjoyed by OLEDs.

Broadly, it is the object of the present invention to provide an improved OLED structure.

These and other objects of the present invention will become apparent to those skilled in the art from the following detailed description of the invention and the accompanying drawings.

### SUMMARY OF THE INVENTION

The present invention is an OLED having top and bottom electrodes with a light-emitting layer sandwiched between these electrodes. The bottom electrode layer includes a planar conducting layer having a plurality of protrusions thereon. The light-emitting layer covers the bottom electrode with a first surface in contact with the first electrode layer and its second surface having raised areas over the protrusions. The top electrode layer includes a layer of conductive material in contact with the second surface. One of the top and bottom electrodes is transparent to light generated in the light-emitting layer. The size and spacing of the protrusions is chosen to provide increased light output from the transparent one of the top and bottom electrodes relative to the light output that would be obtained in the absence of the protrusions.

### BRIEF DESCRIPTION OF THE DRAWINGS

FIG. 1 is a cross-sectional view of a large pixel constructed according to the prior art.

FIG. 2 is a cross-sectional view of a large pixel 20 according to the present invention.

### DETAILED DESCRIPTION OF THE INVENTION

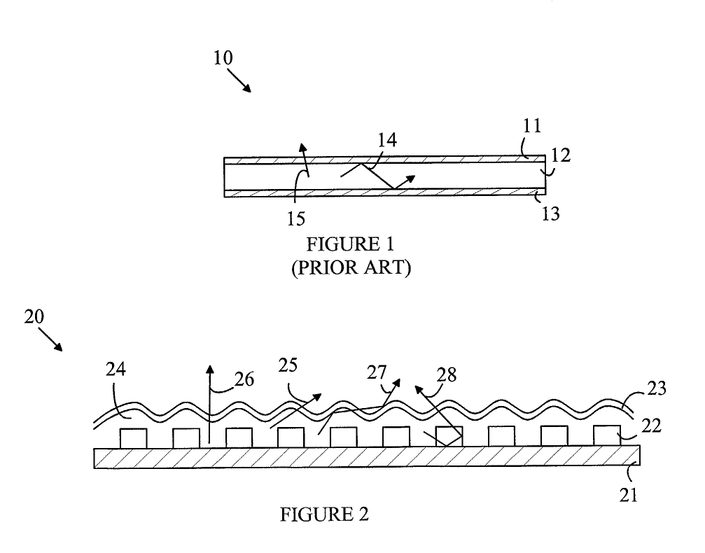

The manner in which the present invention provides its advantages can be more easily understood with reference to FIG. 1, which is a cross-sectional view of a large pixel constructed according to the prior art. Pixel 10 is constructed on a bottom electrode 13 by depositing a light-emitting layer 12 thereon. The light emitting layer may include hole and electron transport layers in addition to an organic electroluminescent layer. Since these layers are well known to the OLED arts, they will not be discussed in detail here. Finally, a top electrode 11 is deposited over the light emitting layer. In the embodiment shown in FIG. 1, the top electrode is assumed to be the transparent layer through which light is extracted.

The index of refraction of the materials used in the light emitting layer is much larger than that of air. Hence, only light that strikes the top electrode at near normal incidence will escape. Such a ray is shown at 15. Light that strikes the top electrode at an oblique angle will be reflected back into the light-emitting layer as shown at 14. This light will be reflected back and forth between the two electrodes until the light either reaches an edge and escapes, or the light is absorbed by the material of layer 12. It should be noted that the materials used in OLEDs are much less transparent than those used in conventional LEDs. Hence, if the point of generation of the light is far from the edge of the pixel, a substantial portion of the internally reflected light will be lost.

The present invention avoids the problems of prior art devices while maintaining the simplicity of fabrication of a large pixel device. Refer now to FIG. 2, which is a cross-sectional view of a large pixel 20 according to the present invention. Pixel 20 is constructed on a substrate 21 having protrusions 22. In the preferred embodiment of the present invention, substrate 21 serves the function of the bottom electrode as well. For example, substrate 21 can be a layer of an aluminum-magnesium alloy deposited on a glass substrate. In the following discussion, the bottom electrode is assumed to be reflecting, and the top electrode is assumed to be transparent. The protrusions can be deposited by conventional lithographic deposition techniques. In the preferred embodiment of the present invention, the protrusions are constructed from SiO2. However, other materials may be utilized including various plastics.

The electroluminescent layer 24 is then deposited over the protrusions using conventional OLED deposition methods. For example, layer 24 may be applied by spin casting. After layer 24 is deposited, a transparent top electrode 23 is deposited thereon. The protrusions introduce undulations in the top surface of layers 23 and 24.

In general, light will be mainly generated in the regions between the protrusions. Light that is generated in a direction that misses the protrusions will strike the transparent electrode boundary at near normal incidence after traveling only a short distance as shown at 25 and 26. Light that is reflected from the boundary at a glancing angle will strike the boundary at near incidence at a nearby location such as shown at 27. Light that is reflected off of the bottom electrode will likewise strike the top electrode at near normal incidence after traveling a short distance. In the preferred embodiment of the present invention, the protrusions are transparent; hence light will either pass through the protrusion without being reflected at the boundary, or the light will be reflected at the boundary and exit the top of the protrusion. Such a reflected ray is shown at 28.

While the embodiment shown in FIG. 2 utilizes a transparent top electrode, embodiments in which the bottom electrode is transparent can also be constructed. In such embodiments, the top electrode reflects light at varying angles back into the bottom electrode. OLEDs in which the bottom electrode is made from indium tin oxide are well known in the OLED arts. Hence, such embodiments can be fabricated by a relatively simple modification of the conventional fabrication process.

The height and spacing of the protrusions must be sufficient to provide an undulating surface that extracts light in the manner described above. In one exemplary embodiment, silicon dioxide protrusions having a square base of approximately 200-400 nm and a height of 100 to 200 nm were found to provide the desired light extraction properties.

Various modifications to the present invention will become apparent to those skilled in the art from the foregoing description and accompanying drawings. Accordingly, the present invention is to be limited solely by the scope of the following claims.

What is claimed is:

1. An OLED comprising:
a bottom electrode layer comprising a planar conducting layer having a plurality of protrusions thereon;
an organic light-emitting layer covering said bottom electrode and having a first surface in contact with said first electrode layer and a second surface, said second surface having raised areas over said protrusions; and
a top electrode layer comprising a layer of conductive material in contact with said second surface, wherein one of said top and bottom electrodes is transparent to light generated in said light-emitting layer.

2. The OLED of claim 1 wherein said protrusions are transparent.

3. The OLED of claim 1 wherein said protrusions comprise SiO₂.

4. The OLED of claim 1 wherein the size and spacing of said protrusions is chosen to provide increased light output from said transparent one of said top and bottom electrodes relative to the light output that would be obtained in the absence of said protrusions.
